(19) United States
(12) Patent Application Publication
(10) Pub. No.: US 2025/0318389 A1
(43) Pub. Date: Oct. 9, 2025

(54) DISPLAY DEVICE, ELECTRONIC DEVICE AND METHOD FOR MANUFACTURING DISPLAY DEVICE

(71) Applicant: Samsung Display Co., LTD., Yongin-si (KR)

(72) Inventors: Seung Hee JANG, Yongin-si (KR); Yeo Geon YOON, Yongin-si (KR); Seung-won PARK, Yongin-si (KR); Jae bok CHANG, Yongin-si (KR); Taek Joon LEE, Yongin-si (KR)

(21) Appl. No.: 19/057,042

(22) Filed: Feb. 19, 2025

(30) Foreign Application Priority Data
Apr. 3, 2024 (KR) 10-2024-0045402

(51) Int. Cl. H10K 59/35; H10K 50/115; H10K 50/16; H10K 59/00; H10K 59/12; H10K 59/122

(52) U.S. Cl. CPC H10K 59/35; H10K 50/115; H10K 50/16; H10K 59/1201; H10K 59/122; H10K 59/771

(57) ABSTRACT

A display device according to one or more embodiments includes: a substrate; a first electrode positioned on the substrate; a hole transport layer positioned on the first electrode; a light emitting layer positioned on the hole transport layer; an electron transport layer positioned on the light emitting layer; and a second electrode positioned on the electron transport layer, wherein the light emitting layer includes a quantum dot, and the electron transport layer includes a hydrophobic ligand.

### CROSS-REFERENCE TO RELATED APPLICATION

The present application claims priority to and the benefit of Korean Patent Application No. 10-2024-0045402, filed on Apr. 3, 2024, in the Korean Intellectual Property Office, the entire content of which is incorporated herein by reference.

### BACKGROUND

### 1. Field

One or more embodiments of the present disclosure relate to a display device, an electronic device including the display device, and a method for manufacturing display device.

### 2. Description of the Related Art

A light emitting element, such as an organic light-emitting element, operates by combining holes supplied from an anode and electrons supplied from a cathode within an emission layer, such as an organic emission layer. This combination forms excitons, which emit light upon decaying to their ground state.

Light-emitting elements/diodes offer several advantages, including a wide viewing angle, fast response speed, thin profile, and low power consumption. Consequently, these elements/diodes, particularly organic light-emitting elements, are widely used in various electronic devices, including televisions, monitors, mobile phones, and/or the like.

### SUMMARY

One or more aspects of embodiments of the present disclosure are directed toward a display device that includes an electron transport layer that concurrently (e.g., simultaneously) plays the roles of protecting quantum dots and transporting electrons (e.g., this layer simultaneously protects quantum dots and transports electrons).

One or more aspects of embodiments of the present disclosure are directed toward an economical and efficient method of manufacturing the display device.

Additional aspects will be set forth in part in the description which follows and, in part, will be apparent from the description, or may be learned by practice of the presented embodiments.

A display device according to one or more embodiments of the present disclosure includes: a substrate; a first electrode on (e.g., positioned on) the substrate; a hole transport layer on (e.g., positioned on) the first electrode; a light emitting layer on (e.g., positioned on) the hole transport layer; an electron transport layer on (e.g., positioned on) the light emitting layer; and a second electrode on (e.g., positioned on) the electron transport layer, wherein the light emitting layer includes a quantum dot, and the electron transport layer includes a hydrophobic ligand.

The light emitting layer may include a first light emitting layer, a second light emitting layer, and a third light emitting layer that are separated from one another by a partition wall and configured to emit light of different colors.

The first light emitting layer, the second light emitting layer, and the third light emitting layer may include red quantum dots, green quantum dots, and blue quantum dots, respectively, and the light emitting layer may include an inorganic material.

The substrate may include a red-light emitting area to emit red light, a green-light emitting area to emit green light, and a blue-light emitting area to emit blue light, and the hole transport layer forms a continuous layer across the red-light emitting area, the green-light emitting area, and the blue-light emitting area.

The electron transport layer may be separated from each other in the red-light emitting area, the green-light emitting area, and the blue-light emitting area by the partition wall. In other words, the electron transport layer is partitioned by the partition wall to correspond to the red-light emitting area, the green-light emitting area, and the blue-light emitting area.

The electron transport layer may include at least one of ZnO, ZnMgO, TiO₂, SnO₂, or ZrO₂.

The hydrophobic ligand may include at least one of hexanethiol, octanethiol, dodecanethiol, or lauric acid.

A manufacturing method of a display device according to one or more embodiments of the present disclosure includes: forming a first electrode on a substrate; forming a hole transport layer on the first electrode; forming a light emitting material layer on the hole transport layer, forming an electron transport material layer on the light emitting material layer, coating a photoresist on the electron transport material layer, exposing the photoresist by placing a mask on the photoresist, developing the photoresist after the exposure to form a patterned photoresist, and etching the electron transport material layer and the light emitting material layer by utilizing the patterned photoresist, wherein the electron transport material layer includes a hydrophobic ligand.

The light emitting material layers may further include a partition wall to separate the light emitting material layer to emit different colors of light from each other.

The light emitting material layer may include red, green, and/or blue quantum dots, and the light emitting material layer includes an inorganic material. The photoresist may be a negative photoresist.

The electron transport material layer may include at least one of ZnO, ZnMgO, TiO₂, SnO₂, or ZrO₂.

In one or more embodiments, the electron transport material layer may be hydrophobic through a fume treatment or a plasma treatment.

In one or more embodiments, the electron transport material layer may be hydrophobic through a solvent treatment.

The solvent may be ethanol.

The hydrophobic ligand may include at least one of hexanethiol, octanethiol, dodecanethiol, or lauric acid.

A developer utilized in the development may have a dielectric constant of 8 to 20.

The developer may include KOH.

The developer may include an orthogonal organic solvent.

The orthogonal organic solvent may include at least one of propylene glycol monomethyl ether acetate (PGMEA) or acetone.

According to one or more embodiments of the present disclosure, by introducing the electron transport layer that concurrently (e.g., simultaneously) functions as protection and electron transport for the quantum dots, an additional electron transport layer coating is unnecessary and/or not required, which enables more economical and efficient manufacturing of the display device.

### BRIEF DESCRIPTION OF DRAWINGS

The accompanying drawing is included to provide a further understanding of the present disclosure and are incorporated in and constitute a part of the present disclosure. The drawing illustrates embodiments of the present disclosure and, together with the description, serve to explain principles of the present disclosure. The above and other aspects, features, and advantages of certain embodiments of the disclosure will be more apparent from the following description taken in conjunction with the accompanying drawings.

FIG. 1 is a cross-sectional view of a display device according to one or more embodiments of the present disclosure.

FIG. 2 is a flowchart of a manufacturing method of a display device according to one or more embodiments of the present disclosure.

FIG. 3-FIG. 7 are cross-sectional views of a manufacturing process of a display device according to one or more embodiments of the present disclosure.

FIG. 8A, FIG. 8B, FIG. 9A, and FIG. 9B are cross-sectional views of a manufacturing process of a display device according to a comparative example of the present disclosure.

FIG. 10 illustrates a block diagram of an electronic device according to one or more embodiments of the present disclosure.

FIG. 11 illustrates schematic diagrams of electronic devices according to one or more embodiments of the present disclosure.

### DETAILED DESCRIPTION

The present disclosure will be described more fully hereinafter with reference to the accompanying drawings, in which example embodiments of present disclosure are shown. As those skilled in the art would realize, the described embodiments may be modified in one or more suitable ways, all without departing from the spirit or scope of the present disclosure.

Descriptions of parts not relevant to the disclosure are not provided, and like reference numerals designate like elements throughout the disclosure, and duplicative descriptions thereof may not be provided for conciseness.

Further, because sizes and thicknesses of constituent members shown in the accompanying drawings are illustratively given for better understanding and ease of description, the present disclosure is not limited to the illustrated sizes and thicknesses. In the drawings, the thicknesses of layers, films, panels, regions, and/or the like, may be exaggerated for clarity. In the drawings, for better understanding and ease of description, the thicknesses of some layers and areas may be exaggerated.

It should be understood that if (e.g., when) an element such as a layer, a film, a region, or a substrate is referred to as being “on” another element, it may be directly on the other element, or one or more intervening elements may also be present therebetween. In contrast, if (e.g., when) an element is referred to as being “directly on” another element, there are no intervening elements present therebetween. Further, in the disclosure, the word “on” or “above” may refer to being positioned on or below the object portion, and does not necessarily refer to being positioned on an upper side of the object portion based on a gravitational direction.

In addition, unless explicitly stated to the contrary, the word “comprise/include/has,” and variations such as “comprises/includes/have” and “comprising/including/having,” should be understood to imply the inclusion of stated elements but not the exclusion of any other elements. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Further, in the disclosure, the phrase “on a plane” refers to viewing an object portion from the top or above, e.g., in a plan view, and the phrase “in a cross-section” refers to viewing a cross-section of which the object portion is vertically cut from the side.

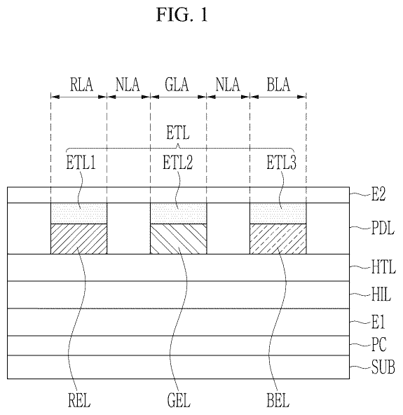

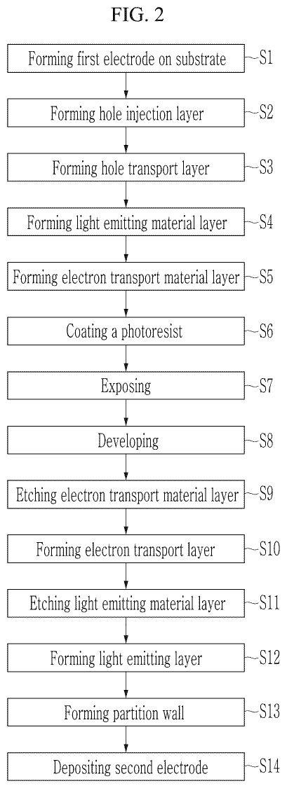

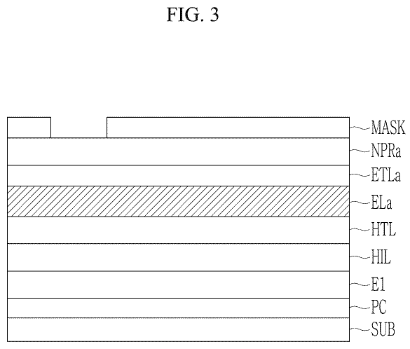

Hereinafter, a display device and a method of manufacturing the display device according to one or more embodiments of the present disclosure will be described in more detail with reference to FIG. 1 to FIG. 7. FIG. 1 is a cross-sectional view of a display device according to one or more embodiments of the present disclosure. FIG. 2 is a flowchart of a manufacturing method of a display device according to one or more embodiments of the present disclosure. FIG. 3 to FIG. 7 are cross-sectional views of a manufacturing process of a display device according to one or more embodiments of the present disclosure.

Referring to FIG. 1, a display device according to one or more embodiments may include a red-light emitting area RLA, a green-light emitting area GLA, and a blue-light emitting area BLA. A non-light emitting area NLA may be positioned between the red-light emitting area RLA, the green-light emitting area GLA, and the blue-light emitting area BLA. Each light emitting area may correspond to a pixel. For example, the blue-light emitting area BLA, the red-light emitting area RLA, and the green-light emitting area GLA may correspond to a blue pixel, a red pixel, and a green pixel, respectively. The shape and arrangement of each of the red-light emitting area RLA, green-light emitting area GLA, and blue-light emitting area BLA may be varied. Embodiments of the present disclosure are not limited thereto.

The display device according to one or more embodiments includes a substrate SUB. The substrate SUB may include a flexible material such as plastic, which may be bent, curved, folded, or rolled or may include a rigid material.

A circuit unit PC may be positioned on the substrate SUB. The circuit unit PC may include a semiconductor layer, a gate electrode, a source electrode, and a drain electrode. In one or more embodiments, the drain electrode may be electrically connected to a first electrode E1 which may be positioned on the circuit unit.

A hole injection layer HIL is positioned on the first electrode E1. In one or more embodiments, the hole injection layer HIL may form (e.g., may be) a single layer continuously across the red-light emitting area RLA, the green-light emitting area GLA, and the blue-light emitting area BLA.

The hole injection layer HIL may include a hole injection material. In one or more embodiments, the hole injection material may include one or more selected from among a phthalocyanine compound such as copper phthalocyanine and/or the like, DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′,4″-tris(N,N-diphenyl amino)tritriphenylamine), 2-TNATA (4,4′,4″-tris{N-(2-naphthyl)-N-phenylamino}-triphenylamine), PEDOT/PSS (Poly(3,4-ethylenedioxythiophene)/Poly(4-styrenesulfonate)), PANI/DBSA (Polyaniline/Dodecylbenzenesulfonic acid), PANI/CSA (Polyaniline/Camphor sulfonic acid), PANI/PSS (Polyaniline/Poly(4-styrenesulfonate)), NPB (N,N′-di(naphthalen-1-yl)-N,N′-diphenyl-benzidine), NPD (N,N′-Di(1-naphthyl)-N,N′-diphenyl-(1,1′-biphenyl)-4,4′-diamine), polyetherketone (TPAPEK) including triphenylamine, 4-Isopropyl-4′-methyldiphenyliodonium [Tetrakis(pentafluorophenyl)borate], HAT-CN (dipyrazino [2,3-f: 2′,3′-h]quinoxaline-2,3,6,7,10,11-hexacarbonitrile), and/or the like.

A hole transport layer HTL is positioned on the hole injection layer HIL. In one or more embodiments, the hole transport layer HTL may be formed as a single layer continuously across the red-light emitting area RLA, the green-light emitting area GLA, and the blue-light emitting area BLA.

The hole transport layer HTL may include a hole transport material. In one or more embodiments, the hole transport material may include, for example, one or more selected from among carbazole-based derivatives such as N-phenylcarbazole, fluorene-based derivatives such as polyvinylcarbazole and/or the like, TPD (N,N′-bis(3-methylphenyl)-N,N′-diphenyl-[1,1-biphenyl]-4,4′-diamine), triphenylamine-based derivatives such as TCTA (4,4′,4″-tris(N-carbazolyl)triphenylamine) and/or the like, NPB (N,N′-di(naphthalen-1-yl)-N,N′-diphenyl-benzidine), TAPC (4,4′-Cyclohexylidene bis[N,N-bis(4-methylphenyl)benzenamine]), HMTPD (4,4′-Bis[N,N′-(3-tolyl)amino]-3,3′-dimethylbiphenyl), mCP (1,3-Bis(N-carbazolyl)benzene), CzSi (9-(4-tert-Butylphenyl)-3,6-bis(triphenylsilyl)-9H-carbazole), and m-MTDATA (4,4′,4″-[tris(3-methylphenyl) phenylamino]triphenylamine).

A first light emitting layer REL, a second light emitting layer GEL, and a third light emitting layer BEL, constituting a light emitting layer, are positioned on the hole transport layer HTL. The first light emitting layer REL, the second light emitting layer GEL, and the third light emitting layer BEL may be separated from one another with a partition wall PDL as a reference and divider. Each of the first light emitting layer REL, the second light emitting layer GEL, and the third light emitting layer BEL may be manufactured through a photolithography process.

The first light emitting layer REL, the second light emitting layer GEL, and the third light emitting layer BEL may be to emit light of different colors. In one or more embodiments, the first light emitting layer REL may be to emit a red light. The first light emitting layer REL may include red quantum dots which emit red light. The second light emitting layer GEL may be to emit a green light. The second light emitting layer GEL may include green quantum dots which emit green light. The third light emitting layer BEL may be to emit a blue light. The third light emitting layer BEL may include blue quantum dots which emit blue light. The first light emitting layer REL, the second light emitting layer GEL and the third light emitting layer BEL may each be an inorganic material.

Below, quantum dots, including the red quantum dots, the green quantum dots, and the blue quantum dots, will be described in more detail.

In the present disclosure, the quantum dots (hereinafter, referred to as semiconductor nanocrystals) may include a Group II-VI compound, a Group III-V compound, a Group IV-VI compound, a Group IV element or compound, a Group I-III-VI compound, a Group II-III-VI compound, a Group I-II-IV-VI compound, and/or one or more (e.g., any suitable) combinations thereof.

The Group II-VI compound may be selected from a group including a binary compound selected from the group consisting of CdSe, CdTe, ZnS, ZnSe, ZnTe, ZnO, HgS, HgSe, HgTe, MgSe, MgS, and a (e.g., any suitable) mixture thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a (e.g., any suitable) mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a (e.g., any suitable) mixture thereof. The Group II-VI compound may further include a Group III metal.

The Group III-V compound may be selected from a group including a binary compound selected from the group consisting of GaN, GaP, GaAs, GaSb, AlN, AlP, AlAs, AlSb, InN, InP, InAs, InSb, and a (e.g., any suitable) mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and a (e.g., any suitable) mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a (e.g., any suitable) mixture thereof. The Group III-V compound may further include a Group II metal (e.g., InZnP).

The Group IV-VI compound may be selected from a group including a binary compound selected from the group consisting of SnS, SnSe, SnTe, PbS, PbSe, PbTe, and a (e.g., any suitable) mixture thereof; a ternary compound selected from the group consisting of SnSeS, SnSeTe, SnSTe, PbSeS, PbSeTe, PbSTe, SnPbS, SnPbSe, SnPbTe, and a (e.g., any suitable) mixture thereof; and a quaternary compound selected from the group consisting of SnPbSSe, SnPbSeTe, SnPbSTe, and a (e.g., any suitable) mixture thereof.

The Group IV element or compound may be selected from a group including single-element compounds selected from the group consisting of Si, Ge, and one or more (e.g., any suitable) combinations thereof; and binary compounds selected from the group consisting of SiC, SiGe, and one or more (e.g., any suitable) combinations thereof.

The Group I-III-VI compound may include CuInSe2, CuInS2, CuInGaSe, and/or CuInGaS. Examples of Group I-II-IV-VI compounds include CuZnSnSe and CuZnSnS, but embodiments of the present disclosure are not limited thereto. The Group IV element or compound may be selected from a group including a single-element compound selected from the group consisting of Si, Ge, and mixtures thereof; and a binary compound selected from the group consisting of SiC, SiGe, and mixtures thereof.

The Group II-III-VI compound may be selected from the group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and one or more (e.g., any suitable) combinations thereof.

The Group I-II-IV-VI compound may be selected from among CuZnSnSe and CuZnSnS, but embodiments of the present disclosure are not limited thereto.

In one or more embodiments, the quantum dots may not include (e.g., may exclude) cadmium. In one or more embodiments, the quantum dots may include a semiconductor nanocrystal based on a Group III-V compound including indium and phosphorus. The Group III-V compound may further include zinc. In one or more embodiments, the quantum dots may include a semiconductor nanocrystal based on a Group II-VI compound including a chalcogen element (e.g., sulfur, selenium, tellurium, and/or one or more (e.g., any suitable) combinations thereof) and zinc.

In the quantum dots, the binary compound, the ternary compound, or the quaternary compound as described above may be present in particles at a substantially uniform concentration or in the same particle with a partially different concentration distribution. Also, they may have a core/shell structure in which one quantum dot surrounds (wraps around) another quantum dot. An interface between the core and the shell may have a concentration gradient in which the concentration of an element present in the shell decreases toward the center.

In one or more embodiments, the quantum dots may have a core-shell structure including a core including the above-described nanocrystal and a shell around (e.g., surrounding) the core. The shell of the quantum dot may act as a protective layer for maintaining the semiconductor properties by preventing or reducing a chemical modification of the core and/or a charging layer for imparting electrophoretic properties to the quantum dot. The shell may be single-layered or multi-layered. In one or more embodiments, the interface between the core and the shell may have a concentration gradient in which the concentration of an element present in the shell decreases toward the center. Non-limiting examples of the shell of the quantum dot may include a metal or non-metal oxide, a semiconductor compound, and/or a (e.g., any suitable) combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or a ternary compound such as MgAl₂O₄, CoFe₂O₄, NiFe₂O₄, CoMn₂O₄, but embodiments of the present disclosure are not limited thereto.

Also, the semiconductor compound suitable as a shell may be exemplified as CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb.

An interface between the core and the shell may have a concentration gradient, such that a concentration of an element existing in the shell is gradually reduced toward the center. In one or more embodiments, the semiconductor nanocrystals may have a structure including one semiconductor nanocrystal core and a multi-layered shell around (e.g., surrounding) the core. In one or more embodiments, the multi-layered shell may have two or more layers—for example, two, three, four, five, or more layers. Two adjacent layers of the shell may have a single composition or different compositions. In the multi-layered shell, each layer may have a composition that varies along the radius.

The quantum dots may have a full width at half maximum (FWHM) of emission spectrum of about 45 nanometers (nm) or less, about 40 nm or less, or about 30 nm or less, and may improve color purity or color reproducibility of emission when the FWHM is within this range. Also, because light emitted through the quantum dots is emitted in all directions, a wide viewing angle may be improved.

In the quantum dots, the shell material and the core material may have different energy bandgaps from each other. For example, in one or more embodiments, the energy bandgap of the shell material may be greater than that of the core material. In one or more embodiments, the energy bandgap of the shell material may be smaller than that of the core material. In one or more embodiments, the quantum dots may have a multi-layered shell. In one or more embodiments, in the multi-layered shell, the energy bandgap of the outer layer may be greater than the energy bandgap of the inner layer (i.e., the layer nearer to the core). In one or more embodiments, in the multi-layered shell, the energy bandgap of the outer layer may be less than the energy bandgap of the inner layer.

The quantum dots may control an absorption/emission wavelength by adjusting a composition thereof and/or a size thereof. A maximum peak emission wavelength of the quantum dot may be an ultraviolet (UV) to infrared wavelength or a wavelength of greater than the aforementioned wavelength range.

The quantum dot may have quantum efficiency of about 10% or more, for example, about 30% or more, about 50% or more, about 60% or more, about 70% or more, about 90% or more, or even 100%. The quantum dots may have a relatively narrow spectrum. The quantum dots may have a full width at half maximum of a light emission spectrum of, for example, about 50 nm or less, about 45 nm or less, about 40 nm or less, or about 30 nm or less.

The quantum dots may have a particle size of about 1 nm or more and about 100 nm or less. In one or more embodiments, the size of the particle refers to a diameter of the particle or a diameter converted by assuming a sphere from a 2-dimensional image obtained by transmission electron microscopy analysis. In one or more embodiments, the quantum dots may have the size of about 1 nm to about 20 nm—for example, 2 nm or more, 3 nm or more, or 4 nm or more, and 50 nm or less, and 40 nm or less, 30 nm or less, 20 nm or less, 15 nm or less, or 10 nm or less. The shape of the quantum dots is not especially limited. For example, the shape of the quantum dots may include a sphere, a polyhedron, a pyramid, a multi-pod, a square, a cuboid, a nanotube, a nanorod, a nanowire, a nanosheet, and/or a (e.g., any suitable) combination thereof, but embodiments of the present disclosure are not limited thereto.

The quantum dots may be commercially available or may be synthesized appropriately or suitably. For the quantum dots, the particle size may be controlled or selected relatively freely during colloid synthesis, and the particle size may also be uniformly (e.g., substantially uniformly) controlled or selected.

In one or more embodiments, the quantum dots may include an organic ligand (e.g., having a hydrophobic moiety or a hydrophilic moiety). The organic ligand may be bound to surfaces of the quantum dots. The organic ligand may include RCOOH, RNH₂, R₂NH, R₃N, RSH, R₃PO, R₃P, ROH, RCOOR, RPO(OH)₂, RHPOOH, R₂POOH, and/or a (e.g., any suitable) combination thereof, and herein, R may each independently be a C3 to C40 substituted or unsubstituted aliphatic hydrocarbon group such as a C3 to C40 (e.g., C5 or greater and C24 or smaller) substituted or unsubstituted alkyl group or a substituted or unsubstituted alkenyl group, a C6 to C40 (e.g., C6 or greater and C20 or smaller) substituted or unsubstituted aromatic hydrocarbon group such as a substituted or unsubstituted C6 to C40 aryl group, and/or a (e.g., any suitable) combination thereof.

Examples of the organic ligand may be: a thiol compound such as methane thiol, ethane thiol, propane thiol, butane thiol, pentane thiol, hexane thiol, octane thiol, dodecane thiol, hexadecane thiol, octadecane thiol, or benzyl thiol; an amine such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, or trioctylamine; a carboxylic acid compound such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, or benzoic acid; a phosphine compound such as methyl phosphine, ethyl phosphine, propyl phosphine, butyl phosphine, pentyl phosphine, octyl phosphine, dioctyl phosphine, tributyl phosphine, or trioctyl phosphine; a phosphine compound or an oxide compound thereof such as methyl phosphine oxide, ethyl phosphine oxide, propyl phosphine oxide, butyl phosphine oxide pentyl phosphine oxide, tributyl phosphine oxide, octyl phosphine oxide, dioctyl phosphine oxide, or trioctyl phosphine oxide; a diphenyl phosphine, a triphenyl phosphine compound, or an oxide compound thereof; a C5 to C20 alkyl phosphinic acid such as hexylphosphinic acid, octylphosphinic acid, dodecane phosphinic acid, tetradecane phosphinic acid, hexadecane phosphinic acid, or octadecane phosphinic acid; and/or the like, but embodiments of the present disclosure are not limited thereto. The quantum dots may include a hydrophobic organic ligand alone or may include a mixture of at least two types (kinds) thereof. The hydrophobic organic ligand may not include (e.g., may exclude) a photopolymerizable moiety (e.g., an acrylate group, a methacrylate group, and/or the like).

Referring again to FIG. 1, a first electron transport layer ETL1 may be positioned on the first light emitting layer REL, a second electron transport layer ETL2 may be positioned on the second light emitting layer GEL, and a third electron transport layer ETL3 may be positioned on the third light emitting layer BEL. The first electron transport layer ETL1, the second electron transport layer ETL2, and the third electron transport layer ETL3 may be separated from one another using the partition wall PDL as a reference and a divider, and may constitute an electron transport layer ETL. The first electron transport layer ETL1, the second electron transport layer ETL2, and the third electron transport layer ETL3 may each be formed through a photolithography process.

According to one or more embodiments, the first electron transport layer ETL1, the second electron transport layer ETL2, and the third electron transport layer ETL3 may include the same electron transport material. The first electron transport layer ETL1, the second electron transport layer ETL2, and the third electron transport layer ETL3 may each include at least one selected from among ZnO, ZnMgO, TiO₂, SnO₂ and ZrO₂.

The first electron transport layer ETL1, the second electron transport layer ETL2, and the third electron transport layer ETL3 may concurrently (e.g., simultaneously) perform the roles of protecting quantum dots and transporting electrons.

The electron transport layer ETL, which includes the first electron transport layer ETL1, the second electron transport layer ETL2, and the third electron transport layer ETL3, may have a hydrophobic ligand. The hydrophobic ligand may include at least one of hexanethiol, octanethiol, dodecanethiol, or lauric acid.

A second electrode E2 is positioned on the first electron transport layer ETL1, the second electron transport layer ETL2, and the third electron transport layer ETL3. In one or more embodiments, the second electrode E2 may be a cathode, which is an electron injection electrode.

According to one or more embodiments, the display device that does not require an additional electron transport layer formation may be provided by having the first electron transport layer ETL1, the second electron transport layer ETL2, and the third electron transport layer ETL3 which concurrently (e.g., simultaneously) function as a preservation layer for preventing or reducing quantum dot property degradation and as an electron transport layer.

Hereafter, the manufacturing method of the display device according to one or more embodiments of FIG. 1 described above will be described in more detail with reference to FIG. 2 to FIG. 7. FIG. 2 is a flowchart of a manufacturing process of a display device according to one or more embodiments of the present disclosure. FIG. 3 to FIG. 7 are cross-sectional views of a manufacturing process of a display device according to one or more embodiments of the present disclosure. Descriptions of components that are identical to or similar to those described above will not be provided for conciseness.

As shown in FIG. 3, the circuit unit PC is first formed on the substrate SUB, and then the first electrode E1 is formed (S1 in FIG. 2) thereon. The hole injection layer HIL is formed on the first electrode E1 (S2 in FIG. 2), and the hole transport layer HTL is formed on the hole injection layer HIL (S3 in FIG. 2). Next, the light emitting material layer ELa is formed on the hole transport layer HTL (S4 in FIG. 2), the electron transport material layer ETLa is formed on the light emitting material layer ELa (S5 in FIG. 2), and a photoresist layer NPRa is coated on the entire surface of the substrate SUB (S6 in FIG. 2). After that, a mask MASK is prepared for a photolithography process. The photoresist layer NPRa may correspond to a negative photoresist.

The light emitting material layer ELa may include any one of red quantum dots, green quantum dots, and/or blue quantum dots (e.g., may include red quantum dots, green quantum dots, and/or blue quantum dots). The light emitting material layer Ela may include (e.g., be) an inorganic material. The phrase “any one of” refers that the light-emitting material layer ELa may include either red, green, or blue quantum dots individually, but not necessarily all three at the same time. However, it may include all three colors. For example, the light-emitting material layer ELa may include red, green, and/or blue quantum dots. Additionally, the light-emitting material layer ELa may be composed of an inorganic material.

The electron transport material layer ETLa may include at least one selected from among ZnO, ZnMgO, TiO₂, SnO₂, and ZrO₂. The electron transport material layer ETLa may include a hydrophobic ligand. The hydrophobic ligand may include at least one of hexanethiol, octanethiol, dodecanethiol, or lauric acid. In one or more embodiments, the electron transport material layer ETLa may be made hydrophobic by a fume treatment, a plasma treatment, or a solvent treatment. An example of the solvent may include ethanol.

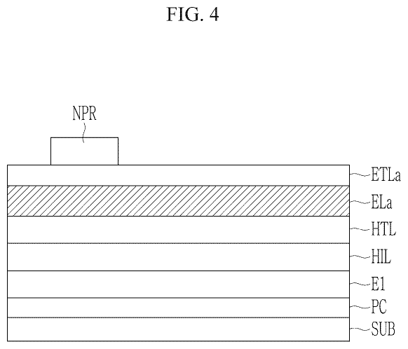

After exposing the photoresist layer NPRa through the mask (S7 in FIG. 2), the exposed photoresist layer NPRa is developed using a developer. Through this, a patterned photoresist layer NPR is formed, as shown in FIG. 4 (S8 in FIG. 2).

In the step (e.g., act or task) (S8 in FIG. 2) of developing the photoresist layer NPRa of FIG. 3 to form the patterned photoresist layer NPR of FIG. 4, the developer may have a dielectric constant of 8 to 20. KOH and/or an orthogonal organic solvent may be used as the developer. Examples of the orthogonal organic solvents may include PGMEA and/or acetone.

For example, due to the dielectric constant of the developer used in the step (e.g., act or task) of forming the patterned photoresist layer NPR (S8 in FIG. 2) being between 8 and 20 and the electron transport material layer ETLa being hydrophobic compared to the photoresist layer NPRa, only the photoresist layer NPRa may be developed without damaging the electron transport material layer ETLa. The electron transport material layer ETLa may be not patterned without being damaged. Therefore, a coating of an additional electron transport material layer ETLa may be unnecessary and may not be required.

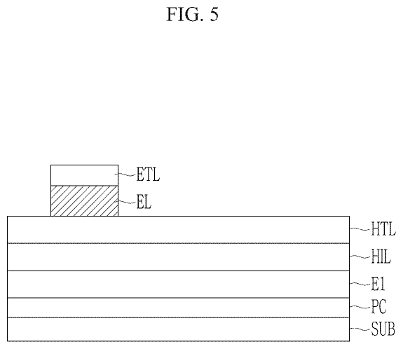

The electron transport material layer ETLa is etched using the patterned photoresist layer NPR of FIG. 4 (S9 in FIG. 2) as a mask, and then the light emitting material layer ELa is etched (S10 in FIG. 2). In this regard, the etching may be done with a dry etching process. The electron transport material layer ETLa and the light emitting material layer ELa are each patterned by etching to form the electron transport layer ETL and the light emitting layer EL, respectively, as shown in FIG. 5.

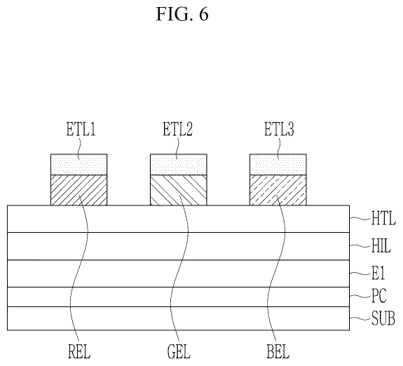

As shown in FIG. 6, the steps (S4) to (S12) of FIG. 2 are repeated twice more to form, as shown in FIG. 1, the first light emitting layer REL, the second light emitting layer GEL, and the third light emitting layer BEL, as well as the first electron transport layer ETL1, the second electron transport layer ETL2, and the third electron transport layer ETL3.

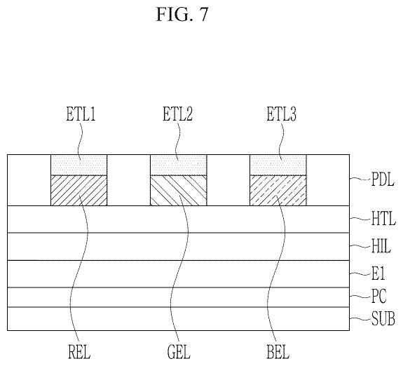

Next, as shown in FIG. 7, the partition wall PDL is formed (S13 in FIG. 2) to separate the first light emitting layer REL and the first electron transport layer ETL1, the second light emitting layer GEL and the second electron transport layer ETL2, and the third light emitting layer BEL and the third electron transport layer ETL3 from one another. The partition wall PDL may be formed through a photolithography process.

By depositing the second electrode E2 (S14 in FIG. 2), the display device having the structure similar to FIG. 1 may then be manufactured.

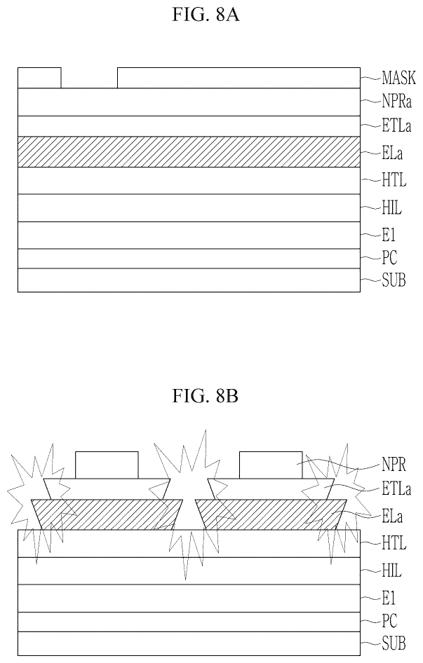

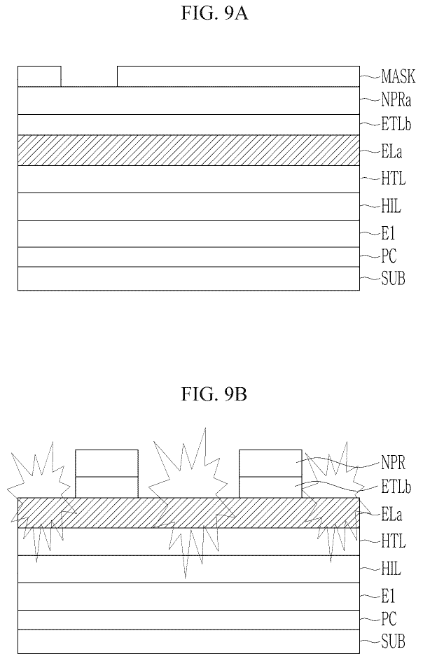

Below, a display device manufactured according to a comparative example will be described in more detail with reference to FIG. 8A, FIG. 8B, FIG. 9A and FIG. 9B.

FIG. 8A according to the comparative example is a cross-sectional view of a display device prepared for the photolithography process. FIG. 8B is a cross-sectional view showing a result of using a developer whose dielectric constant is not between 8 and 20 in the developing step (e.g., act or task) of the photoresist layer NPRa (S8 in FIG. 2).

In the comparative example, the developer used is specifically tetramethylammonium hydroxide (TMAH). When TMAH is used as a developer, the exposed portion of the photoresist layer NPRa or a portion other than the exposed portion is developed, enabling normal patterning. However, there is a problem in that the photoresist layer NPRa is patterned to form the patterned photoresist layer NPR and concurrently (e.g., simultaneously) the electron transport material layer ETLa and the light emitting material layer ELa are also partially developed. This causes damage to the electron transport material layer ETLa and the light emitting material layer ELa. According to the process according to FIG. 8A and FIG. 8B, the display device may not be manufactured due to damage to the electron transport material layer ETLa and the light emitting material layer ELa.

FIG. 9A according to another comparative example is a cross-sectional view of a display device prepared for performing the photolithography process. However, the comparative example of FIG. 9A uses a hydrophilic electron transport material layer ETLb instead of a hydrophobic electron transport material layer ETLa. FIG. 9B is a cross-sectional view showing a patterning result using KOH as a developer. When the hydrophilic electron transport material layer ETLb is applied, a problem occurs in that the photoresist layer NPRa is patterned to form the patterned photoresist layer NPR and the hydrophilic electron transport material layer ETLb is also developed concurrently (e.g., simultaneously). This causes damage to the hydrophilic electron transport material layer ETLb and/or the light emitting material layer ELa. According to the process according to FIG. 9A and FIG. 9B, an additional coating of the electron transport material layer ETL may be desired or required.

According to the manufacturing method of the display device according to one or more embodiments of the present disclosure, the electron transport layer ETL plays a role in protecting quantum dots and concurrently (e.g., simultaneously) plays a role in electron transport while being preserved without being damaged in the development process of the photoresist layer NPRa, so that additional coating of the electron transport layer ETL may be unnecessary and may not be required. Therefore, the process for forming a new layer or removing an existing layer becomes unnecessary, thereby providing a more economical and efficient display manufacturing process.

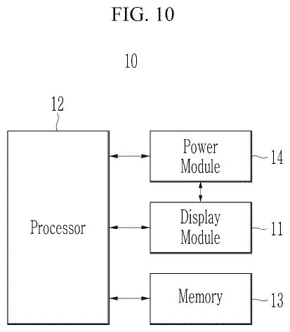

The display device according to one or more embodiments of the present disclosure may be applied to one or more suitable electronic devices. An electronic device according to one or more embodiments may include the display device, and may further include modules or devices having additional functions other than the display device. FIG. 10 is a block diagram of an electronic device according to one or more embodiments of the present disclosure. Referring to FIG. 10, an electronic device 10 according to one or more embodiments may include a display module 11, a processor 12, a memory 13, and a power module 14. The processor 12 may include at least one of a central processing unit (CPU), an application processor (AP), a graphic processing unit (GPU), a communication processor (CP), an image signal processor (ISP), or a controller. The memory 13 may store data information necessary for operations of the processor 12 and/or the display module 11. When the processor 12 executes an application stored in the memory 13, video data signals and/or input control signals are transmitted to the display module 11, and the display module 11 may process the received signals to output video information through the display screen. The power module 14 may include a power supply module such as a power adapter or a battery device, and a power conversion module that converts the power supplied by the power supply module to generate the power necessary for the operation of the electronic device 10. At least one of components of the electronic device 10 may be included within the display device according to the above-described embodiments. In one or more embodiments, some of the individual modules that are functionally included within a single module may be incorporated into the display device, while others may be provided separately from the display device. For example, in one or more embodiments, the display device may include the display module 11, while the processor 12, memory 13, and power module 14 may be provided in a form of other devices within the electronic device 10 that are not part of the display device.

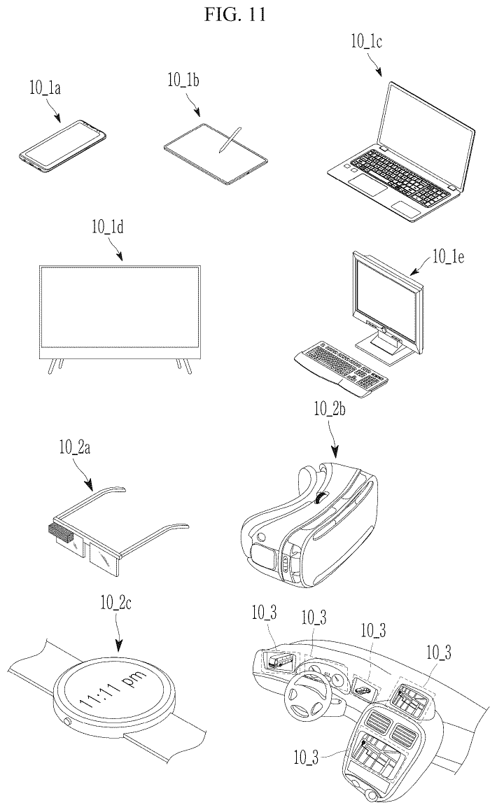

FIG. 11 shows schematic diagrams of electronic devices according to one or more embodiments of the present disclosure. Referring to FIG. 11, one or more suitable electronic devices with the display device according to one or more embodiments may include not only image display electronic devices such as smartphones 10_1a, tablet PCs 10_1b, laptops 10_1c, TVs 10_1d, and desktop monitors 10_1e, but also wearable electronic devices with display modules such as smart glasses 10_2a, head-mounted displays 10_2b, and smart watches 10_2c, as well as automotive electronic devices with display modules 10_3 such as those placed on car dashboards, center fascias, CID (Center Information Display), room mirror displays, and/or the like.

In the context of the present disclosure and unless otherwise defined, the terms “use,” “using,” and “used” may be considered synonymous with the terms “utilize,” “utilizing,” and “utilized,” respectively.

In the present disclosure, the terms “at least any one of A, B, and C,” “at least any one of A, B, or C,” “at least any one selected from among A, B, and C,” and “at least any one selected from the group consisting of A, B, and C” may be construed as each of A, B, and C or a (e.g., any suitable) combination of two or more of A, B, and C (for example, ABC, ABB, BC, and CC). As used herein, “and/or” or “or” may include one or more combinations of corresponding components.

It will be understood that, although the terms “first,” “second,” “third,” and so on may be used herein to describe one or more suitable elements, these elements are not limited by these terms. These terms are used to distinguish one element from another element. Thus, a first element described could also be termed as a second or third element without departing from the spirit and scope of the disclosure. As utilized herein, the singular forms “a,” “an,” and “the” are intended to include the plural forms as well, unless the context clearly indicates otherwise. Further, the use of “may” when describing embodiments of the present disclosure refers to “one or more embodiments of the present disclosure.

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” other elements or features would then be oriented “above” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display device, the electronic device/apparatus, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

While this disclosure has been described in connection with what is presently considered to be example embodiments, it is to be understood that the present disclosure is not limited to the disclosed embodiments, but, on the contrary, is intended to cover one or more suitable modifications and equivalent arrangements included within the spirit and scope of the appended claims and equivalents thereof.

### REFERENCE LETTERS

RLA: red-light emitting area
GLA: green-light emitting area
BLA: blue-light emitting area
NLA: non-light emitting area
E1: first electrode
PC: circuit unit
HIL: hole injection layer
HTL: hole transport layer
REL: first light emitting layer
GEL: second light emitting layer
BEL: third light emitting layer
EL: light emitting layer
ELa: light emitting material layer
PDL: partition wall
ETL: electron transport layer
ETL1: first electron transport layer
ETL2: second electron transport layer
ETL3: third electron transport layer
ETLa: electron transport material layer
ETLb: hydrophilic electron transport material layer
E2: second electrode
NPRa: photoresist layer
NPR: patterned photoresist layer
MASK: mask

What is claimed is:

1. A display device comprising:
a substrate;
a first electrode on the substrate;
a hole transport layer on the first electrode;
a light emitting layer on the hole transport layer;
an electron transport layer on the light emitting layer; and
a second electrode on the electron transport layer,
wherein,
the light emitting layer comprises a quantum dot, and
the electron transport layer comprises a hydrophobic ligand.

2. The display device of claim 1, wherein:
the light emitting layer comprises a first light emitting layer, a second light emitting layer, and a third light emitting layer that are separated from one another by a partition wall and configured to emit light of different colors.

3. The display device of claim 2, wherein:
the first light emitting layer comprises red quantum dots,
the second light emitting layer comprises green quantum dots,
the third light emitting layer comprise blue quantum dots, and
the light emitting layer comprises an inorganic material.

4. The display device of claim 2, wherein:
the substrate comprises
a red-light emitting area configured to emit red light,
a green-light emitting area configured to emit green light, and
a blue-light emitting area configured to emit blue light, and
the hole transport layer is a continuous layer across the red-light emitting area, the green-light emitting area, and the blue-light emitting area.

5. The display device of claim 4, wherein:
the electron transport layer is partitioned by the partition wall to correspond to the red-light emitting area, the green-light emitting area, and the blue-light emitting area.

6. The display device of claim 1, wherein:
the electron transport layer comprises at least one of ZnO, ZnMgO, TiO₂, SnO₂, or ZrO₂.

7. The display device of claim 1, wherein:
the hydrophobic ligand comprises at least one of hexanethiol, octanethiol, dodecanethiol, or lauric acid.

8. A manufacturing method comprising:
forming a first electrode on a substrate;
forming a hole transport layer on the first electrode;
forming a light emitting material layer on the hole transport layer;
forming an electron transport material layer on the light emitting material layer;
coating a photoresist on the electron transport material layer;
exposing the photoresist by placing a mask on the photoresist;
developing the photoresist after the exposure to form a patterned photoresist; and
etching the electron transport material layer and the light emitting material layer by utilizing the patterned photoresist,
wherein the electron transport material layer comprises a hydrophobic ligand, and
wherein the manufacturing method is a manufacturing method of a display device.

9. The manufacturing method of claim 8, further comprising:
forming a partition wall so that the light emitting material layer is partitioned to emit light of different colors.

10. The manufacturing method of claim 8, wherein:
the light emitting material layer comprises red, green, and/or blue quantum dots, and the light emitting material layer further comprises an inorganic material.

11. The manufacturing method of claim 8, wherein:
the photoresist is a negative photoresist.

12. The manufacturing method of claim 8, wherein:
the electron transport material layer comprises at least one of ZnO, ZnMgO, TiO₂, SnO₂, or ZrO₂.

13. The manufacturing method of claim 8, wherein:
the electron transport material layer is hydrophobic through a fume treatment or a plasma treatment.

14. The manufacturing method of claim 8, wherein:
the electron transport material layer is hydrophobic through a solvent treatment.

15. The manufacturing method of claim 14, wherein:
the solvent comprises ethanol.

16. The manufacturing method of claim 8, wherein:
the hydrophobic ligand comprises at least one of hexanethiol, octanethiol, dodecanethiol, or lauric acid.

17. The manufacturing method of claim 8, wherein:
a developer utilized in the development has a dielectric constant between 8 and 20.

18. The manufacturing method of claim 17, wherein:
the developer comprises KOH.

19. The manufacturing method of claim 17, wherein:
the developer comprises an orthogonal organic solvent, and the orthogonal organic solvent comprises at least one of propylene glycol monomethyl ether acetate or acetone.

20. An electronic device comprising:
a memory;
a processor configured to execute an application stored in the memory; and
a display device comprising a display module outputting video information provided by the application, wherein
the display device comprising:
a substrate;
a first electrode on the substrate;
a hole transport layer on the first electrode;
a light emitting layer on the hole transport layer;
an electron transport layer on the light emitting layer; and
a second electrode on the electron transport layer,
wherein,
the light emitting layer comprises a quantum dot, and
the electron transport layer comprises a hydrophobic ligand.
